(19) United States
(12) Patent Application Publication
(10) Pub. No.: US 2014/0354363 A1
(43) Pub. Date: Dec. 4, 2014

(54) POWER AMPLIFIER

(71) Applicant: POSTECH ACADEMY-INDUSTRY FOUNDATION, NAM-GU (KR)

(72) Inventors: Bum Man Kim, Daejam Central Heights (KR); Sang su Jin, Ocean city 8-ro 22beongil (KR)

(73) Assignee: POSTECH ACADEMY-INDUSTRY FOUNDATION, NAM-GU (KR)

(21) Appl. No.: 14/288,457

(22) Filed: May 28, 2014

(30) Foreign Application Priority Data
May 31, 2013 (KR) 10-2013-0062394

(51) Int. Cl. H03F 1/22; H03F 3/21

(52) U.S. Cl. CPC H03F 1/223; H03F 3/211
USPC 330/296

(57) ABSTRACT

The present disclosure relates to a power amplifier, the power amplifier comprising a first amplifier including at least two first transistors whose sources are commonly connected to form a common source, a second amplifier including at least two second transistors whose gates are commonly connected to form a common gate, the at least two second transistors being connected to the at least two first transistors in a cascode structure; and a bias supplier configured to apply to the common gate of the second amplifier a bias voltage that changes in response to an input and output power.

Pursuant to 35 U.S.C.§119 (a), this application claims the benefit of earlier filing date and right of priority to Korean Patent Application No.10-2013-0062394, filed on May 31, 2013, the contents of which are hereby incorporated by reference in their entirety.

### BACKGROUND OF THE DISCLOSURE

1. Technical Field

The teachings in accordance with the exemplary embodiments of this present disclosure generally relate to a power amplifier.

2. Background

In recent years, many demands are required to integrate wireless transceiver into a single chip, and researches into the integration of wireless transceiver in a single chip have been actively conducted. However, among the blocks of the wireless transceiver, only a power amplifier is implemented by using an indium gallium phosphide (InGaP)/gallium arsenide (GaAs) heterojunction bipolar transistor (HBT) process.

Compared with the CMOS (Complementary Metal Oxide Semiconductor) process, the InGaP/GaAs HBT process incurs high manufacturing costs, is required to have a multi-chip structure, and has difficulty in being coupled to a control circuit block implemented according to the CMOS process to improve linearity. For these reasons, researches into a power amplifier based on the CMOS process have been actively implemented because a wireless transceiver can be manufactured in a single chip.

In a case of employing a power amplifier based on the CMOS process in order to cope with the abovementioned problems, a power amplifier is employed that has a cascode structure in which a plurality of transistors are stacked due to low breakdown voltage characteristics of a CMOS element compared with the case in which the foregoing HBT process is employed.

The most fundamental cascode amplifier structure is configured by using a common source amplifier in a first layer positioned at an input terminal and a common gate amplifier in a second layer positioned at an output terminal, by which manner common gate amplifiers may be added to third and fourth layers to thereby enhance a breakdown voltage characteristic. An external power is supplied to the power amplifier for amplifying operation.

Generally, a common gate node of differential structure is formed with a virtual ground at the common gate node due to differential operation, and provides a ground to an odd harmonic component. A node of the cascode amplifier is applied with an external power using the common gate node. The external power is supplied to a gate of common source, a gate of common gate and a drain of a common gate in case of 2-stage cascode amplifier structure.

FIG. 1 is a schematic view illustrating a structure of a power amplifier using a CMOS device according to prior art that employs a differential cascode structure. A common source amplifier (110) at an input terminal functions as a main amplification section, and a common gate amplifier is used for reducing a breakdown voltage.

Generally, a power amplifier is classified based on bias voltage into a class-A mode, a class-B mode and a class-AB mode power amplifier. The class-A mode power amplifier amplifies all phases of input signals without any loss and is used for small signal amplification or for audio purposes. The class-B mode power amplifier has an increased efficiency compared to class-A mode power amplifier, albeit being of great signal transformation, by way of amplifying a half of phase of input signal and discarding the other half In order to prevent the signal transformation, a push-pull structure is generally employed in which two class-B mode power amplifiers are connected where two amplifiers alternately amplify and a sum of two outputs are used. The class-AB mode power amplifier is a combination of class-A and class-B mode power amplifiers, and, albeit of being similar to the push-pull structure, amplifies a region higher than 50% of an input signal like that of class-B mode power amplifier. Thus, noise can be removed using a signal of opposite region, the moment the phase is changed.

The class-A mode power amplifier has a high linearity but generally has a poor efficiency rating, while the class-AB mode power amplifier is considered to have a good efficiency but a low linearity. The class-B mode power amplifier has a low linearity but generally has a high efficiency rating. The conventional power amplifier uses a bias of medium shape between the class-A mode and class-AB mode operations due to the abovementioned characteristics.

FIGS. 2A and 2B are schematic views illustrating linearity and efficiency of a power amplifier at each mode of bias.

Referring to FIG. 2A, an efficiency of class-B is better or equal to that of class-A in all output powers. Meantime, as illustrated in FIG. 2B, it can be noted that the linearity of class-A is good at a region lower than an output power of 5 dBm and the linearity of class-AB is good at a region higher than 5 dBm. The reason is that a distortion is generated due to an operation near a turn-on voltage when class-AB or class-B bias is supplied at a lower output power.

A power amplifier 100 as in FIG. 1 is a serial two-stage amplifier formed with a common source amplifier 110 and a common gate amplifier 120. In designing a conventional two-stage amplifier, a linearity improving method is generally employed where a one-stage amplifier supplies a class-A bias voltage and a two-stage amplifier supplies class-AB or class-B bias voltage to thereby improve an AM-AM (Amplitude Modulation to Amplitude Modulation) characteristic of an entire amplifier.

FIG. 3A is a structural view of a power amplifier according to prior art and FIG. 3B is an exemplary view illustrating a bias voltage provided to a common gate node of FIG. 3A. Referring to FIGS. 3A and 3B, a cascode structure of conventional power amplifier requires a trade-off in a linearity and efficiency due to being supplied with a fixed common gate bias.

### SUMMARY OF THE DISCLOSURE

The present disclosure is to provide a power amplifier configured to improve linearity and efficiency by enhancing AM-AM characteristic of the cascode structured amplifier by providing class-A and class-B mode bias voltages to a gate bias in response to input/output power.

In one general aspect of the present disclosure, there is provided a power amplifier comprising: a first amplifier including at least two first transistors whose sources are commonly connected to form a common source; a second amplifier including at least two second transistors whose gates are commonly connected to form a common gate, the at least two second transistors being connected to the at least two first transistors in a cascode structure; and a bias supplier configured to apply to the common gate of the second amplifier a bias voltage that changes in response to an input and output power.

In some exemplary embodiment of the present invention, the bias supplier may be further configured to apply the bias voltage to the common gate node of the second amplifier by determining the bias voltage to allow decreasing from an initial bias voltage when the input and output power increases.

In some exemplary embodiment of the present invention, the bias supplier may include a detector configured to detect an envelope curve of the input power, and a distributor configured to decrease an initial bias voltage in response to an output of the detector and distribute the decreased initial bias voltage.

In some exemplary embodiment of the present invention, the output of the detector may decrease when the envelope curve of the input power increases.

In some exemplary embodiment of the present invention, the distributor may include a third transistor, and is further configured to increase a resistance of the third transistor when the output of the detector decreases.

In some exemplary embodiment of the present invention, the power amplifier may further comprise: a resistor and a capacitor connected in series between a gate of the first transistor and a drain of the second transistor.

In some exemplary embodiment of the present invention, the first and second amplifiers may be arranged in differential cascode structure.

In some exemplary embodiment of the present invention, the first and second amplifiers may be arranged in single cascode structure.

In some exemplary embodiment of the present invention, the power amplifier may further comprise a balloon unit configured to convert a single signal to a balance signal and to provide the converted balance signal to the first amplifier.

In some exemplary embodiment of the present invention, the power amplifier may further comprise a matching unit configured to match impedance on a signal path between an output terminal of the second amplifier and an output terminal of the power amplifier.

In some exemplary embodiment of the present invention, the first amplifier may be arranged in a multiple-layered cascode structure.

### ADVANTAGEOUS EFFECT OF THE DISCLOSURE

The power amplifier of cascode structure according to the present disclosure thus described has an advantageous effect in that class-A and class-B mode bias voltages are individually applied to a common gate of a second amplifier in response to input/output power to improve linearity to allow being used as a linear power amplifier free from application of pre-distortion circuit.

Another advantageous effect is that a bias supplier according to an exemplary embodiment of the present disclosure has almost no influence on an entire efficiency due to use of a small current of −3 mA, whereby a high degree of efficiency can be obtained over a general power amplifier.

### BRIEF DESCRIPTION OF DRAWINGS

FIG. 1 is a schematic view illustrating a structure of a power amplifier using a CMOS device according to prior art.

FIGS. 2A and 2B are schematic views illustrating linearity and efficiency of a power amplifier at each mode of bias.

FIG. 3A is a structural view of a power amplifier according to prior art and FIG. 3B is an exemplary view illustrating a bias voltage provided to a common gate node of FIG. 3A.

FIG. 4 is a circuit diagram illustrating a power amplifier according to an exemplary embodiment of the present disclosure.

FIG. 5 is a detailed circuit diagram illustrating a bias supplier of FIG. 4 according to the present disclosure.

FIG. 6 is a schematic view illustrating IMD3 according to gate bias of a first amplifier (10) of FIG. 4.

FIG. 7 is a schematic view illustrating a characteristic function of a power amplifier (1) relative to a gate bias of a second amplifier (20) and a differential function thereof

FIG. 8 is a schematic view illustrating IMD3 in response to an output power at mutually different Vcg.

FIG. 9 is a schematic view illustrating Vcg bias in response to an input power level at a power amplifier according to an exemplary embodiment of the present disclosure.

FIG. 10 is a schematic view illustrating IMD3 in response to mutually different Vcg.

FIG. 11 is a schematic view illustrating a concept of a power amplifier according to an exemplary embodiment of the present disclosure.

FIG. 12 is a schematic view illustrating IMD3, PAE and gain change characteristic of a power amplifier according to the present disclosure.

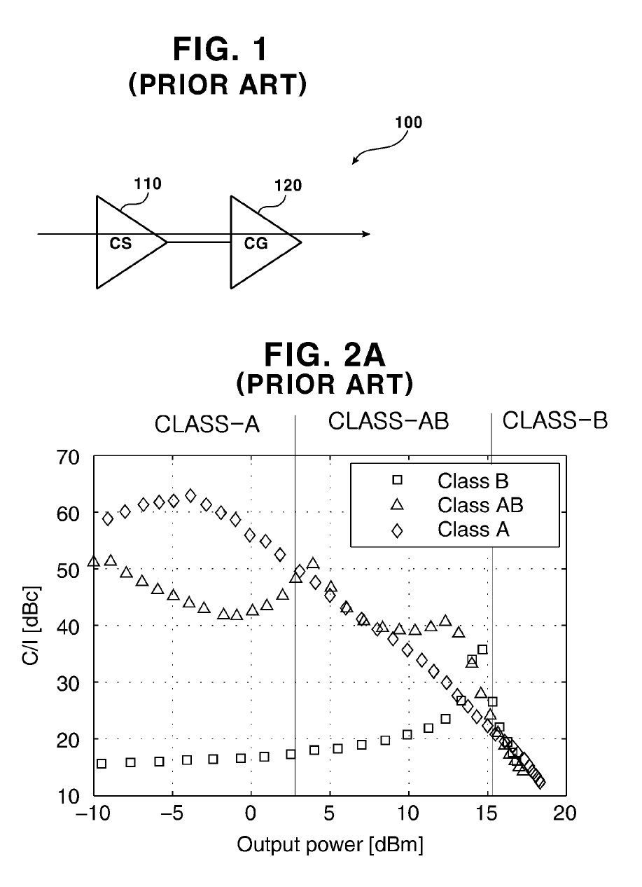

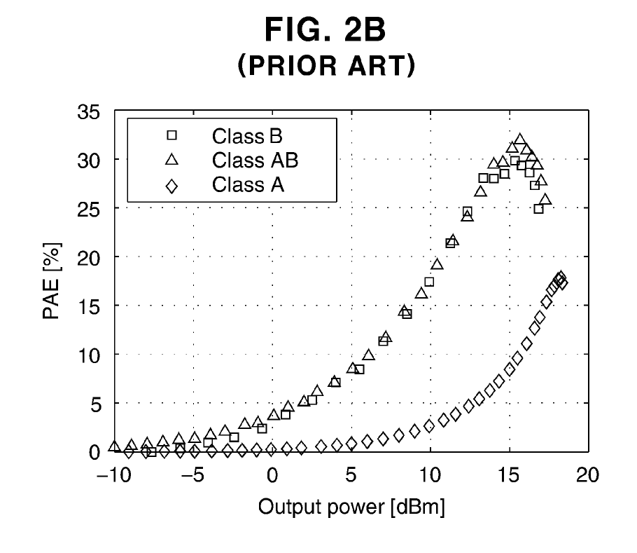

### DETAILED DESCRIPTION OF THE DISCLOSURE

Various exemplary embodiments will be described more fully hereinafter with reference to the accompanying drawings, in which some exemplary embodiments are shown. The present inventive concept may, however, be embodied in many different forms and should not be construed as limited to the example embodiments set forth herein. Rather, the described aspect is intended to embrace all such alterations, modifications, and variations that fall within the scope and novel idea of the present disclosure.

Now, an exemplary embodiment of the present disclosure will be described in detail with reference to the accompanying drawings.

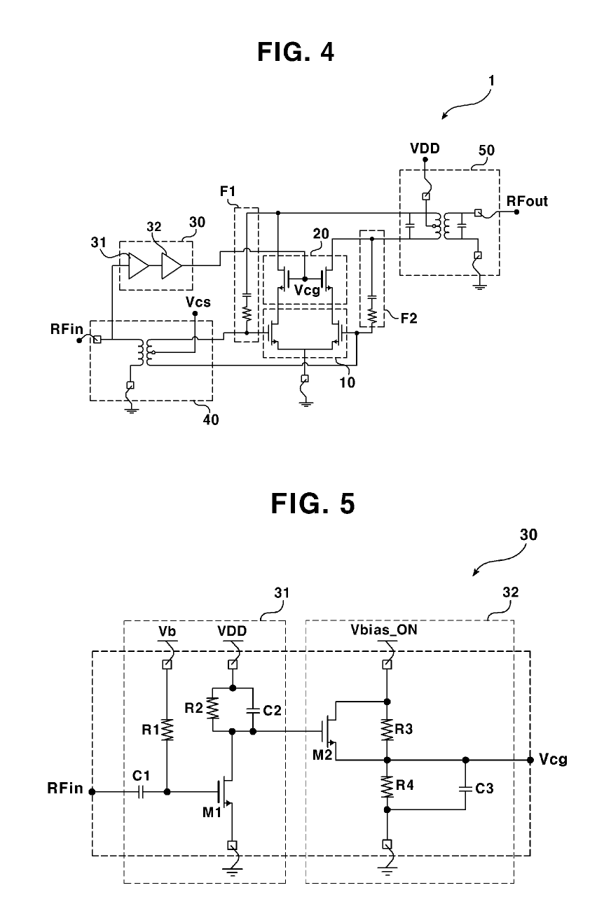

FIG. 4 is a circuit diagram illustrating a power amplifier (1) according to an exemplary embodiment of the present disclosure.

Referring to FIG. 4, the power amplifier (1) according to the exemplary embodiment of the present disclosure may include a first amplifier (10), a second amplifier (20) configured to be connected to the first amplifier in a cascode structure, and a bias supplier (30).

The power amplifier (1) according the exemplary embodiment of the present disclosure may further include a balloon unit (40) and an impedance matching unit (50), in addition to the first amplifier (10), the second amplifier (20) and the bias supplier (30). The first and second amplifiers (10, 20) of the power amplifier (1) according the exemplary embodiment of the present disclosure may be embodied by CMOS process.

The first and second amplifiers (10, 20) are connected in a cascode structure, where the cascode structure means that a transistor device of the first amplifier (10) and a transistor device of the second amplifier (20) are respectively connected in series. Although the exemplary embodiment of the present disclosure has explained and described a configuration where the first and second amplifiers (10, 20) are serially connected by two transistors in a cascode structure, the present disclosure is not limited thereto, the number of amplifiers is not limited and two or more plural number of transistors may be connected to form a cascode structure.

Furthermore, although FIG. 4 illustrates a power amplifier in a differential cascode structure according to an exemplary embodiment of the present disclosure, it should be noted that a single cascode structure of power amplifier is not ruled out. That is, it would be apparent to the skilled in the art that, as described hereunder, the first and second amplifiers (10, 20) may be constituted in one transistor, and a bias voltage may be supplied to a source of the first amplifier (10) or to a gate of the second amplifier (20), instead of a configuration of a bias voltage is supplied to the common source of the first amplifier (10) or to the common gate of the second amplifier (20).

Furthermore, although the power amplifier (1) of the present disclosure has illustrated a two-stage cascode structure of the first amplifier (10) and the second amplifier (20), the present disclosure is not limited thereto, and a multi-stage cascode structure may be formed. That is, the present disclosure may be configured in such a manner that the first amplifier (10) is configured in a multi-stage cascode structure and the second amplifier (20) may be configured in the common gate node.

The first amplifier (10) operates as a main amplifier, where a plurality of transistors may be connected in parallel, and sources of a plurality of transistors may be commonly connected to form the common source.

The second amplifier (20) performs an amplification operation for mitigating a breakdown voltage from the first amplifier (10), where a plurality of transistors may be connected in parallel to form the common gate by connecting a plurality of gates of the plurality of transistors.

Transistors of the first and second amplifiers (10, 20) may be MOSFETs (Metal-Oxide-Semiconductor Field-Effect Transistors), but the transistors of the first and second amplifiers (10, 20) are not limited thereto.

The signal amplification operation of first and second amplifiers (10, 20) is apparent to the skilled in the art and therefore no further descriptions will be made thereto.

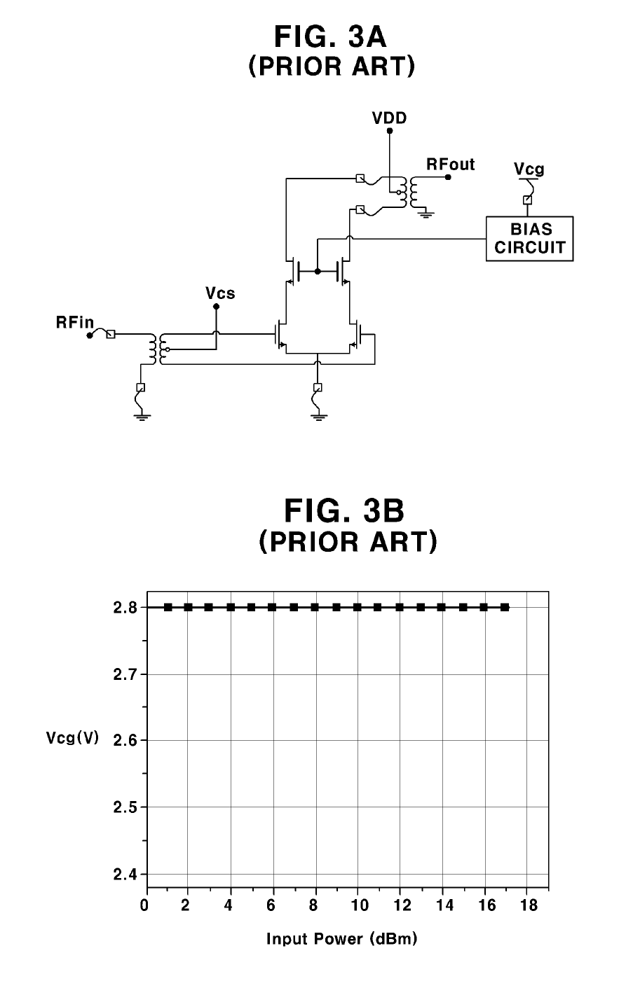

Unlike the conventional power amplifier (1) of FIG. 3A, the bias supplier (30) of the present disclosure uses an input signal(RFin), and as illustrated in the drawing, the bias supplier (30) may include an envelope curve detector (31) and a bias distributor (32).

FIG. 5 is a detailed circuit diagram illustrating a bias supplier of FIG. 4 according to the present disclosure.

Referring to FIG. 5, the envelope curve detector (31) according to the exemplary embodiment of the present disclosure may include a first transistor (M1), resistors (R1, R2) and capacitors (C1, C2), and the bias distributors (32) may include a second transistor (M2), resistors (R3, R4) and a capacitor (C3). Although the first and second transistors (M1, M2) according to the exemplary embodiment of the present disclosure may be N MOSFET, it should be apparent that the given configuration is for exemplary purpose and not limited thereto.

Now, operation of bias supplier (30) of the present disclosure will be described in detail.

In order for the power amplifier to obtain a high degree of efficiency, a sweet spot must exist in a high power region of IMD3 (third-order InterModulation Distortion), which can be realized by bias of gate of the first amplifier (10) at deep class-AB. However, the power amplifier (1) at the deep class-AB bias exhibits a very serious nonlinearity characteristic near at a turn-on voltage to generate an increased IMD3 at a low power region.

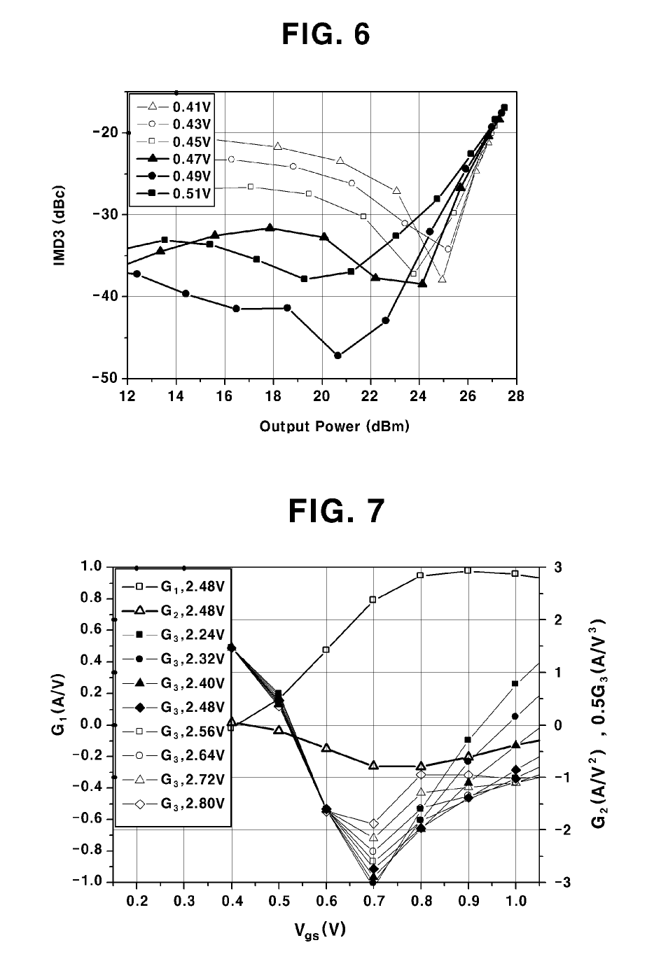

FIG. 6 is a schematic view illustrating IMD3 according to gate bias of a first amplifier (10) of FIG. 4, where IMD3 is shown in response to output power relative to mutually different gate biases of the first amplifier (10), when a gate bias of the second amplifier (20) is Vcg=2.8V. A drain current (iDS) of the power amplifier (1) may be expanded as in the following Equation 1 by the Taylor series, and may be used for finding the IMD3 characteristic.

i_{DS}(V_{GS}υ_{GS})=i_{DS}(V_{GS})+G₁υ_{gs}+G₂υ²_{gs}+G₃υ³_{gs}+. . . [Equation 1]

A drain current of the power amplifier (1) at a region where a signal is great is affected by a drain bias and a gate bias. The drain bias of the first amplifier (10) is determined by a gate bias of the second amplifier (2) in a cascode structure according to the following Equation 2.

V_{drain}^{^{—}}_{CS}=V_{cg}+Vₑₙᵥ^{^{—}}_{signal}−Vₜₕ^{^{—}}_{CG} [Equation 2]

where, Vcg is a gate bias of the second amplifier (20), Vth_CG is a threshold voltage of the second amplifier (20) and Venv_signal is an input envelope curve signal.

FIG. 7 is a schematic view illustrating a characteristic function of a power amplifier (1) relative to a gate bias of a second amplifier (20) and a differential function thereof

Referring to FIG. 7, when a transition point of G3 exists at Vcg of 0.8V, and Vcg decreases at Vgs under 0.8V, G3 increases, and alternatively, when Vcg increases at Vgs over 0.8V, G3 decreases. The generation of IMD3 may differ according to Vcg by the mutually different G3 value of FIG. 7.

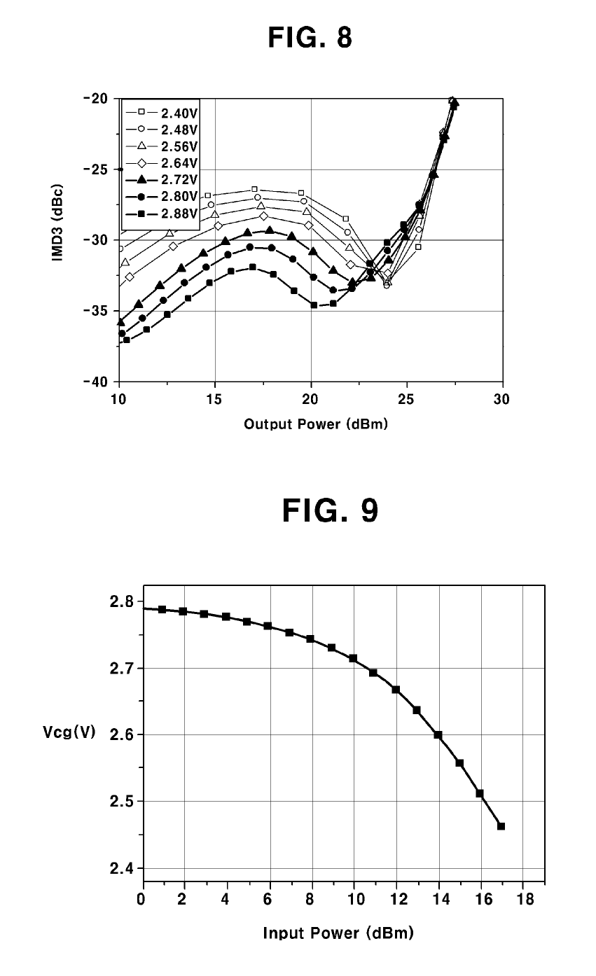

FIG. 8 is a schematic view illustrating IMD3 in response to an output power at mutually different Vcg when Vgs is 0.45V.

For linear operation, Vcg must have a high bias relative to Vgs under 0.8V, and must have a low bias above the transition point.

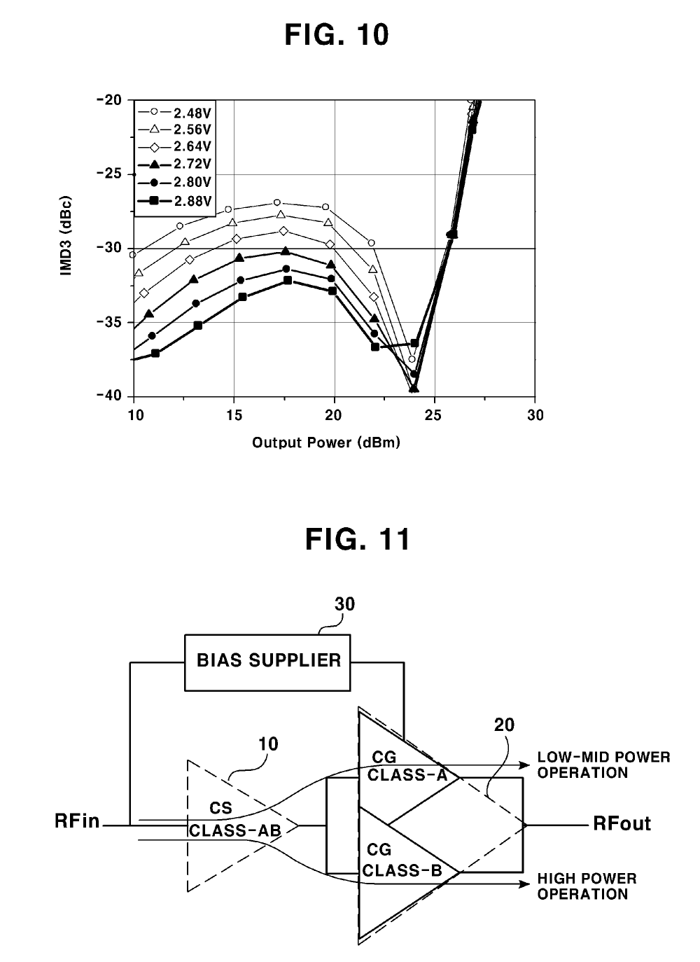

FIG. 9 is a schematic view illustrating Vcg bias in response to an input power level at a power amplifier according to an exemplary embodiment of the present disclosure, where an initial value (VcgO) is 2.8V. Furthermore, FIG. 10 is a schematic view illustrating IMD3 in response to mutually different Vcg at Vgs=0.45V, and the indicated value is an initial value provided by the bias supplier (30).

As illustrated in FIG. 10, it can be noted that IMD3 is improved by 5 dB at low-mid power over that of FIG. 8, and improved by 2.5 dB at high power.

Referring to FIG. 4 again, the power amplifier (1) according to the present disclosure is used to improve the linearity and stability of resistor and capacitors (F1, F2) serially connected between the gate of the first amplifier (10) and the drain of the second amplifier (20).

The envelope curve detector (31) of the bias supplier (30) according to the present disclosure serves to detect an envelope of an input power. When an envelope curve signal increases, that is, when the input power increases, an output of the envelope curve detector (31) decreases. At this time, a resistor of a second transistor (M2) of the bias distributor (32) gradually increases to distribute an inputted initial bias voltage (Vbias), whereby Vcg changes by decreasing from the initial bias voltage.

However, it should be apparent that any circuit configuration configured to change a bias voltage in response to an input power including that of the bias supplier (30) as illustrated in FIG. 9, for example, may be within the scope of the present disclosure. That is, it should be apparent to the skilled in the art that many circuits configured to decrease a bias voltage of the second amplifier (20) in response to the increased input power may be designed, in addition to that of the bias supplier (30) of FIG. 4.

The balloon unit (40) may include a primary winding (P) and a secondary winding (S), whereby a single signal (RFin) is converted to a balance signal and provided to the first amplifier (10). The impedance matching unit (50) may match impedances on a signal path between an output terminal of the second amplifier (20) and an output terminal (RFout) of the power amplifier (1).

FIG. 11 is a schematic view illustrating a concept of a power amplifier according to an exemplary embodiment of the present disclosure.

Referring to FIG. 11, the power amplifier (1) of the present disclosure may include a first amplifier (10), a second amplifier (20) and a bias supplier (30).

The first amplifier (10) of common source structure according to an exemplary embodiment of the present disclosure may operate in the class-AB mode, and the second amplifier (20) of common gate structure may be configured in such a manner that a bias voltage is supplied to the common gate to allow operating in class-A mode at low-mid power, and a bias voltage is supplied to the common gate to allow operating in class-B mode at a high power.

Although FIG. 11 has described two amplifiers for the second amplifier (20), it should be apparent to the skilled in the art that this is to explain changes in operation of amplifier in response to power and to explain two modes of operation for one amplifier

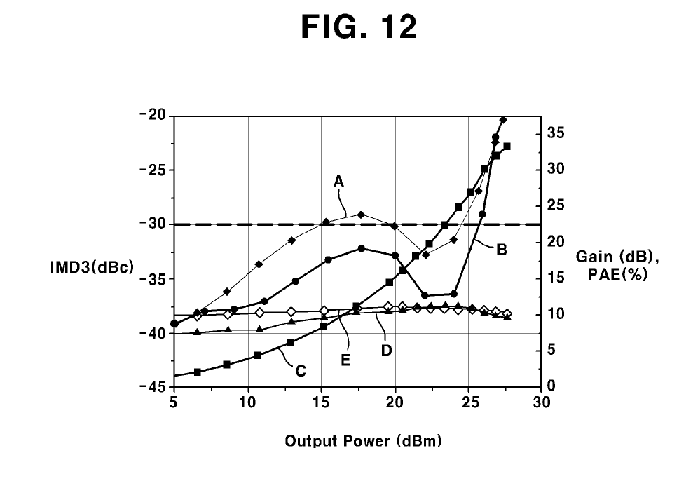

FIG. 12 is a schematic view illustrating IMD3, PAE and gain change characteristic of a power amplifier according to the present disclosure, where A illustrates an IMD3 in a case where a fixed bias voltage is supplied to the common gate of the power amplifier as in FIG. 3 according to prior art, and B illustrates an IMD3 in a case where a bias voltage that changes in response to an input/output power applied to the common gate of the power amplifier according to the present disclosure, and C illustrates a PAE (Power Added Efficiency) of the power amplifier according to the present disclosure. Furthermore, D illustrates a gain change of a power amplifier according to prior art, and E illustrates a gain change of a power amplifier according to the present disclosure.

Referring to FIG. 12, it can be noted that the power amplifier according to the present disclosure has improved in IMD3 characteristic by A and B over that of the prior art, and linearity is improved to thereby enhance the degree of efficiency due to by the improved IMD3 characteristic (C).

It can be also noted that gain change relative to an output power change is lowered by D and E in the power amplifier according to the present disclosure, and AM-AM distortion is also decreased due to decreased gain expansion characteristic.

Generally, a cascode power amplifier of CMOS method is not adequate for use in a linear power amplifier due to bad linearity, and therefore a sufficient degree of linearity can be obtained only by applying an external circuit such as a pre-distortion circuit or an envelope tracking circuit.

However, the degree of linearity can be improved by individually applying a bias voltage to the common gate of the second amplifier (20) in class-A and class-B mode in response to input/output power, whereby the cascode power amplifier of CMOS method can be used for a linear power amplifier free from usage of pre-distortion circuit.

Furthermore, the bias supplier according to the exemplary embodiment of the present disclosure uses a small size of current (−3 mA) to obtain a higher degree of efficiency over the conventional power amplifier with little influence on an entire efficiency.

Although the present disclosure has been described in detail with reference to the foregoing embodiments and advantages, many alternatives, modifications, and variations will be apparent to those skilled in the art within the metes and bounds of the claims Therefore, it should be understood that the above-described embodiments are not limited by any of the details of the foregoing description, unless otherwise specified, but rather should be construed broadly within the scope as defined in the appended claims

What is claimed is:

1. A power amplifier comprising:
a first amplifier including at least two first transistors whose sources are commonly connected to form a common source;
a second amplifier including at least two second transistors whose gates are commonly connected to form a common gate, the at least two second transistors being connected to the at least two first transistors in a cascode structure; and
a bias supplier configured to apply to the common gate of the second amplifier a bias voltage that changes in response to an input and output power.

2. The power amplifier of claim 1, wherein the bias supplier is further configured to apply the bias voltage to the common gate node of the second amplifier by determining the bias voltage to allow decreasing from an initial bias voltage when the input and output power increases.

3. The power amplifier of claim 1, wherein the bias supplier includes:
a detector configured to detect an envelope curve of the input power, and
a distributor configured to decrease an initial bias voltage in response to an output of the detector and distribute the decreased initial bias voltage.

4. The power amplifier of claim 3, wherein the output of the detector decreases when the envelope curve of the input power increases.

5. The power amplifier of claim 4, wherein the distributor includes a third transistor, and is further configured to increase a resistance of the third transistor when the output of the detector decreases.

6. The power amplifier of claim 1, further comprising:
a resistor and a capacitor connected in series between a gate of the first transistor and a drain of the second transistor.

7. The power amplifier of claim 1, wherein the first and second amplifiers are arranged in differential cascode structure.

8. The power amplifier of claim 1, wherein the first and second amplifiers are arranged in single cascode structure.

9. The power amplifier of claim 1, further comprising:
a balloon unit configured to convert a single signal to a balance signal and to provide the converted balance signal to the first amplifier.

10. The power amplifier of claim 1, further comprising:
a matching unit configured to match impedance on a signal path between an output terminal of the second amplifier and an output terminal of the power amplifier.

11. The power amplifier of claim 1, wherein the at least two first transistors of the first amplifier is arranged in a multiple-layered cascode structure.
